(19) United States
(12) Patent Application Publication
(10) Pub. No.: US 2025/0159967 A1
(43) Pub. Date: May 15, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wen-Li CHIU, Hsinchu (TW); Hong-Chih CHEN, Hsinchu (TW); Chia-Hao KUO, Hsinchu (TW); Fu-Hsiang SU, Hsinchu (TW); Shih-Hsun CHANG, Hsinchu (TW)

(73) Assignee: Taiwan Semiconductor Manufacturing Company, Ltd., Hsinchu (TW)

(21) Appl. No.: 18/510,011

(22) Filed: Nov. 15, 2023

(51) Int. Cl. H01L 21/8234; H01L 27/088; H01L 29/06; H01L 29/423; H01L 29/66; H01L 29/775

(52) U.S. Cl. CPC H10D 84/038; H10D 30/014; H10D 30/43; H10D 30/6735; H10D 62/121; H10D 64/017; H10D 84/0151; H10D 84/83

(57) ABSTRACT

A semiconductor device includes a plurality of active components and an isolation component. Each active component includes a plurality of active channel sheets vertically stacked and a metal gate. The isolation component isolates the adjacent two of the active components, and includes a plug structure. The plug structure is formed of a material the same as that of the metal gate.

### BACKGROUND

A semiconductor device generally includes a plurality of active components and an isolation component isolating the adjacent two of the active components. However, a CMP applied to the active components and the isolation component may form a poor flatness surface due to the active component and the isolation component being different in property.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a cross-sectional view of a semiconductor device according to an embodiment of the present disclosure;

FIG. 2 illustrates a schematic diagram of a cross-sectional view of a semiconductor device according to an embodiment of the present disclosure; and

FIGS. 3A to 3H illustrate schematic diagrams of manufacturing processes of the semiconductor device in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

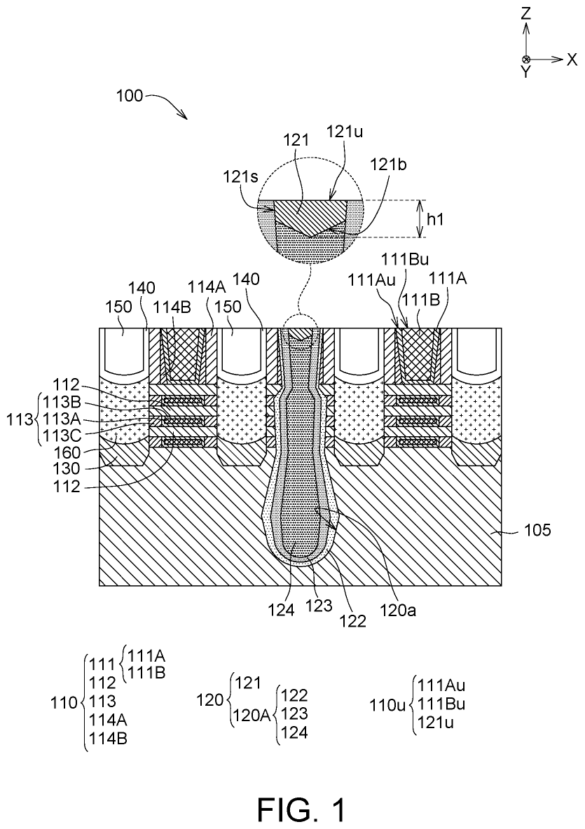

Referring to FIG. 1, FIG. 1 illustrates a schematic diagram of a cross-sectional view of a semiconductor device 100 according to an embodiment of the present disclosure.

The semiconductor device 100 may include a substrate 105, at least one active component 110, at least one isolation component 120, at least one pure silicon layer 130, at least one contact etch stop layer (CESL) 140, at least one oxide layer 150 and at least one epitaxy layer 160. Each active component 110 includes at least one gate 111. The isolation component 120 isolates the adjacent two of the active components 110, and includes at least one plug structure 121. The plug structure 121 is formed of a material the same as that of the metal gate 111. Due to the same material, a planarized surface of the semiconductor device 100 formed in CMP process may have better flatness. In addition, the plug structure 121 has a height h1 ranging between, for example, 3 nanometers (nm) to 5 nanometers, even greater or less.

In an embodiment, the active component 110 may be at least one portion of a CMOS (Complementary Metal Oxide Semiconductor) component, nanosheet structure, fin-FET, etc. In an embodiment, the isolation component 120 may be called “COPDE”, wherein the “COPDE” means a lithography/etch/thin film deposition processes that used to define “isolation” boundaries between cell units, which is usually composed of SiN material to meet isolation requirement.

As illustrated in FIG. 1, the metal gate 111 includes a first high-k layer 111A and a first metal 111B, wherein the first metal 111B is formed on the first high-k layer 111A. The plug structure 121 is a second high-k layer. In an embodiment, the first high-k layer 111A may be formed of a material the same as that of the second high-k layer. In the present embodiment, the plug structure 121 is a top portion of the isolation component 120. For example, the plug structure 121 is a topmost portion of the isolation component 120. In another embodiment, the plug structure 121 may be omitted.

In some embodiments, the first metal 111B may be formed of a work function metal. The work function metal may be an N-type or P-type work function layer. Exemplary P-type work function metals include TiN, TaN, Ru, Mo, Al, WN, ZrSi2, MoSi2, TaSi2, NiSi2, WN, other suitable P-type work function materials, or combinations thereof. Exemplary N-type work function metals include Ti, Ag, TaAl, TaAlC, TiAlN, TaC, TaCN, TaSiN, Mn, Zr, other suitable N-type work function materials, or combinations thereof. The work function layer may contain multiple layers. The work function metal may be formed by a process such as ALD, CVD, PVD, remote plasma CVD (RPCVD), plasma enhanced CVD (PECVD), metal-organic CVD (MOCVD), sputtering, electroplating, other suitable processes, or the like. Formed by suitable processes such as combination.

The high-k layer may be formed of a material including: (i) a high-k dielectric material, such as hafnium oxide (HfO₂), titanium oxide (TiO₂), hafnium zirconium oxide (HfZrO), tantalum oxide (Ta2O3), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9).

As illustrated in FIG. 1, the first high-k layer 111A has a first upper surface 111Au, the first metal 111B has a first upper surface 111Bu, and the plug structure 121 has a second upper surface 121u. The semiconductor device 100 has a planarized surface 100u at least including the first upper surface 111Au of the first high-k layer 111A, the first upper surface 111Bu of the first metal 111B and the second upper surface 121u of the plug structure 121. In process of CMP (Chemical Mechanical Polishing), the material removed by the CMP is the same material (for example, the first high-k layer 111A and the plug structure 121), and thus the planarized surface 100u may have better flatness. For example, a step height (if any) between the first upper surface 111Au and the second upper surface 121u in Z-axis may range between 1 nm and 2 nm, or even less. In an embodiment, the first upper surface 111Au and the second upper surface 121u are substantially flush with each other. In other words, due to the small number of material types, the planarized surface 100u formed by CMP may have better flatness.

As illustrated in FIG. 1, each active component 110 further includes a plurality of active channel sheets 112 vertically stacked, a plurality of composite layers 113, a first dielectric layer 114A and a second dielectric layer 114B. The active channel sheet 112 may be formed of a material, for example, silicon. One of the composite layers 113 is formed between adjacent two of the active channel sheets 112. Each composite layer 113 includes a metal portion 113A, a high-k dielectric portion 113B and an inner spacer 113C, wherein the metal portion 113A may be surrounded by the high-k dielectric portion 113B, the high-k dielectric portion 113B covers a portion of the active channel sheet 112, the inner spacer 113C is formed on a lateral surface of the high-k dielectric portion 113B or the active channel sheet 112.

As illustrated in FIG. 1, the first dielectric layer 114A and the second dielectric layer 114B are formed above the active channel sheet 112. The second dielectric layer 114B is formed between the first dielectric layer 114A and the first metal 111B. In addition, the first dielectric layer 114A may be formed of a material different from that of the second dielectric layer 114B. In an embodiment, the first dielectric layer 114A may be formed from a material including one of SiO, SiN, SiOC, SiON and SiOCN, and the second dielectric layer 114B may be formed from a material including another of SiO, SiN, SiOC, SiON and SiOCN.

As illustrated in FIG. 1, the pure silicon layer 130 is formed within a trench between adjacent two of the active structures 110, and located between the substrate 105 and the epitaxy layer 160.

As illustrated in FIG. 1, the CESL 140 is formed above the epitaxy layer 160. The CESL 140 is formed between the epitaxy layer 160 and the oxide layer 150. The CESL 140 may be formed from a material including SiO, SiN, SiOC, SiON or SiOCN. The oxide layer 150 is formed on the CESL 140.

As illustrated in FIG. 1, the isolation component 120 has an isolation hole 120a and further includes a dielectric structure 120A, wherein the dielectric structure 120A is formed within the isolation hole 120a. The isolation component 120 fills the isolation hole 120a. In the present embodiment, the isolation component 120 may fill the entirety of the isolation hole 120a. In other words, there is no void or space within the isolation hole 120a. Furthermore, the dielectric structure 120A includes a first dielectric layer 122, a second dielectric layer 123 and a third dielectric layer 124, wherein the isolation hole 120a may be filled with the plug structure 121, the first dielectric layer 122, the second dielectric layer 123 and the third dielectric layer 124.

As illustrated in FIG. 1, the first dielectric layer 122 is formed on an inner sidewall of the isolation hole 120a, and the second dielectric layer 123 is formed between the first dielectric layer 122 and the third dielectric layer 124. In the present embodiment, the plug structure 121 is formed within the isolation hole 120a and above or over the third dielectric layer 124. In addition, the second dielectric layer 123 covers a lateral surface 121s of the plug structure 121, and the third dielectric layer 124 covers a bottom 121b of the plug structure 121.

In an embodiment, the first dielectric layer 122 may be formed of a material including oxide, the second dielectric layer 123 may be formed of a material including SiN (silicon nitride), and the third dielectric layer 124 may be formed of a material including ALD oxide. In addition, the first dielectric layer 122 may have a thickness of, for example, 1 nanometer (nm), the second dielectric layer 123 may have a thickness of, for example, 3 nm, and the third dielectric layer 124 may have a thickness of, for example, 25 nm.

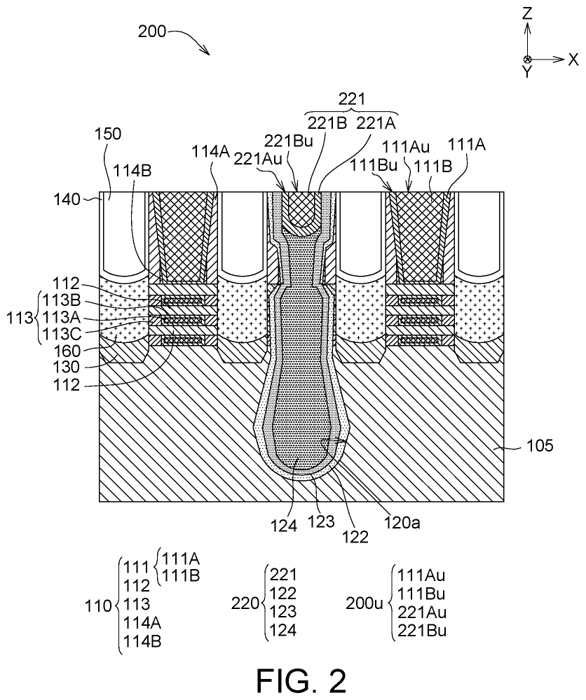

Referring to FIG. 2, FIG. 2 illustrates a schematic diagram of a cross-sectional view of a semiconductor device 200 according to an embodiment of the present disclosure. The semiconductor device 200 may include the substrate 105, at least one active component 110, at least one isolation component 120, at least one pure silicon layer 130, at least one CESL 140, at least one oxide layer 150 and at least one epitaxy layer 160. Each active component 110 includes at least one gate 111. The isolation component 120 isolates the adjacent two of the active components 110, and includes at least one plug structure 221. The plug structure 221 is formed of a material the same as that of the metal gate 111. Due to the same material, a planarized surface of the semiconductor device 200 formed in CMP process may have better flatness.

In an embodiment, the active component 210 may be at least one portion of a CMOS component, nanosheet structure, fin-FET, etc. In an embodiment, the isolation component 220 may be called “COPDE”, wherein the “COPDE” means a lithography/etch/thin film deposition processes that used to define “isolation” boundaries between cell units, which is usually composed of SiN material to meet isolation requirement.

The semiconductor device 200 includes the features the same as or similar to those of the semiconductor device 100, and the difference is that the plug structure 221 of the semiconductor device 200 is different from the plug structure 121 of the semiconductor device 100.

As illustrated in FIG. 2, the metal gate 111 includes the first high-k layer 111A and the first metal 111B, and the plug structure 221 includes a second high-k layer 221A and a second metal 221B, wherein the first high-k layer 111A is formed of a material the same as that of the second high-k layer 221A, and the first metal 111B is formed of a material the same as that of the second metal 221B.

As illustrated in FIG. 2, the first high-k layer 111A has the first upper surface 111Au, and the first metal 111B has the first upper surface 111Bu. The second high-k layer 221A has a second upper surface 221Au, and the second metal 221B has a second upper surface 221Bu. The semiconductor device 200 has a planarized surface 200u at least including the first upper surface 111Au of the first high-k layer 111A, the first upper surface 111Bu of the first metal 111B, the second upper surface 221Au of the second high-k layer 221A and the second upper surface 221Bu of the second metal 221B. In process of CMP, the material removed by the CMP is the same material (for example, the first high-k layer 111A is formed of a material the same as that of the second high-k layer 221A, and the first metal 111B is formed of a material the same as that of the second metal 221B), and thus the planarized surface 200u may have better flatness. For example, a step height (if any) between two of the first upper surface 111Au, the first upper surface 111Bu, the second upper surface 221Au and the second upper surface 221Bu in Z-axis is equal to or less 1 nm. In an embodiment, the first upper surface 111Au, the first upper surface 111Bu, second upper surface 221Au and the second upper surface 221Bu are substantially flush with each other. In other words, due to the small number of material types, the planarized surface 200u formed by CMP may have better flatness. In addition, in another embodiment, the plug structure 221 may be omitted.

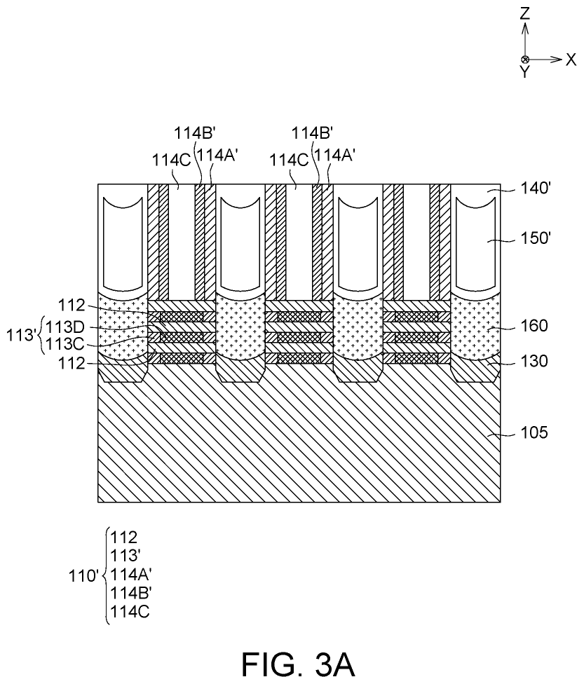

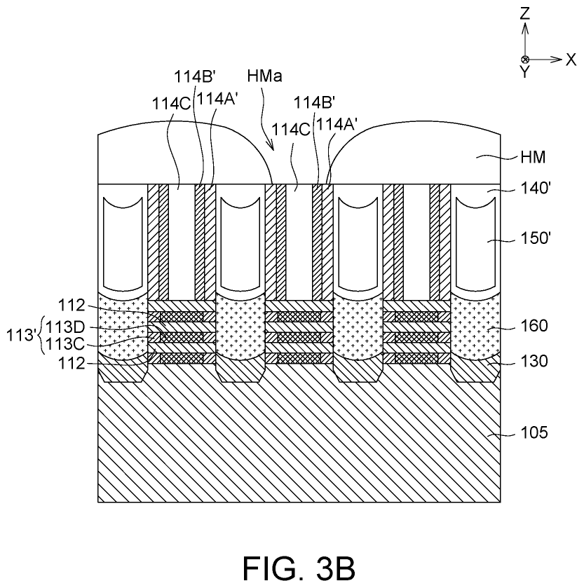

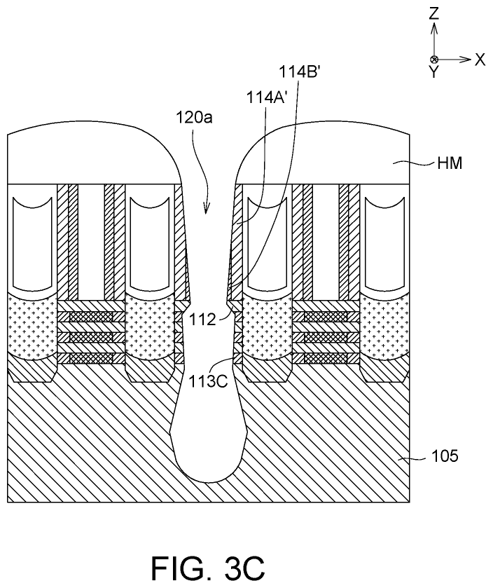

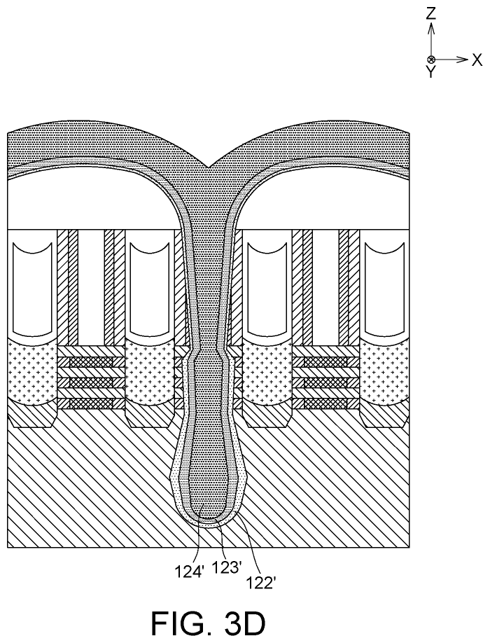

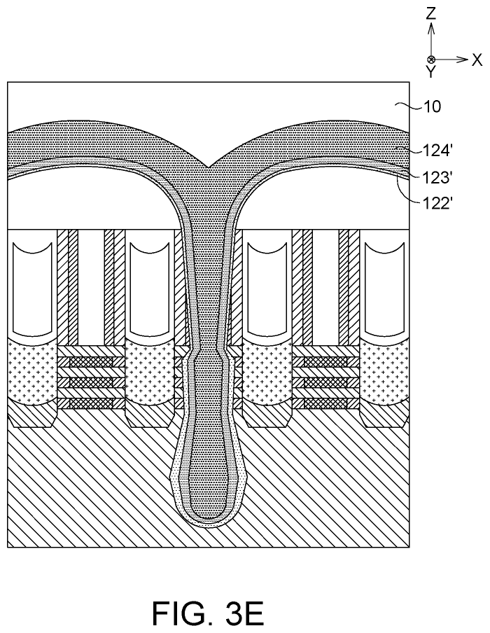

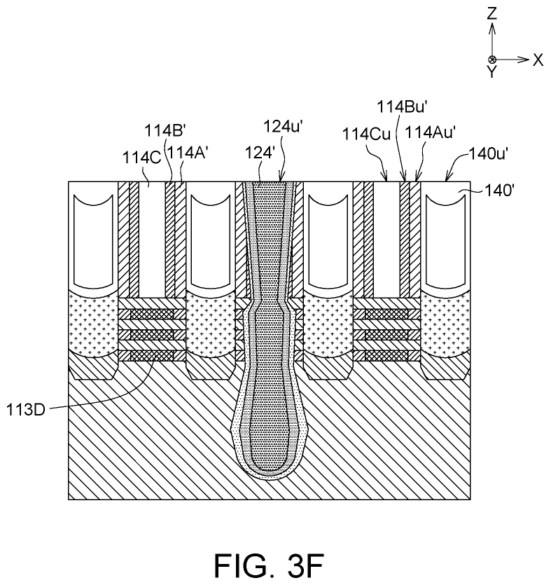

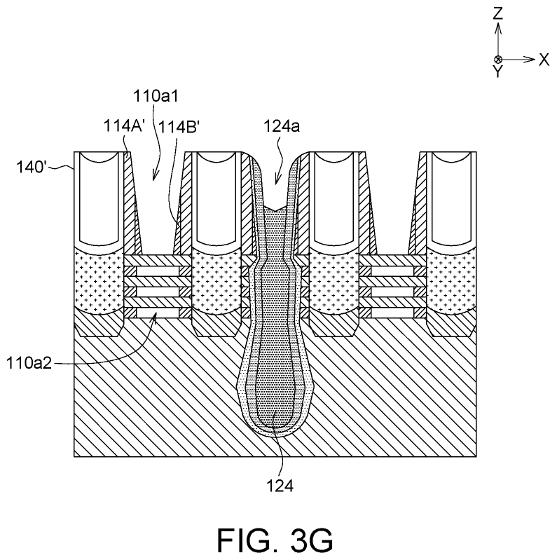

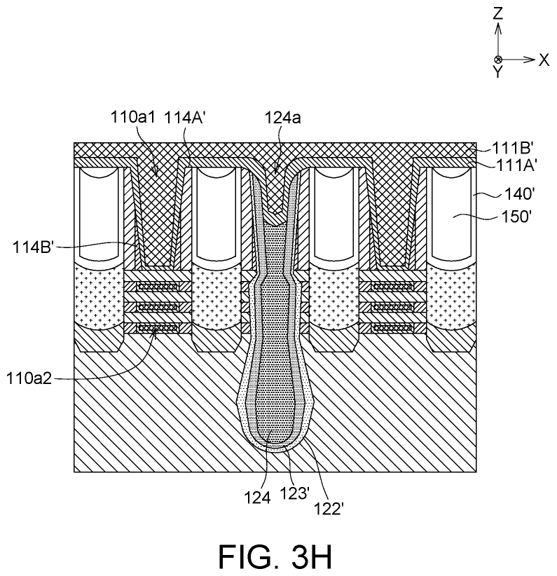

Referring to FIGS. 3A to 3H, FIGS. 3A to 3H illustrate schematic diagrams of manufacturing processes of the semiconductor device 100 in FIG. 1.

As illustrated in FIG. 3A, at least one active component 110′ is formed on the substrate 105. Each active component 110′ includes a plurality of the active channel sheets 112, a plurality of composite layers 113′, a first dielectric layer materials 114A′, a second dielectric layer materials 114B′ and a dummy gates 114C.

In FIG. 3A, one of the composite layers 113′ is formed between adjacent two of the active channel sheets 112. Each composite layer 113′ includes the inner spacer 113C and a SiGe layer 113D, wherein the inner spacer 113C is formed on a lateral surface of the SiGe layer 113D.

In FIG. 3A, there is a trench between adjacent two of the active structures 110′. The pure silicon layer 130 is formed within a bottom portion of the trench and located between the substrate 105 and the epitaxy layer 160, and the epitaxy layer 160 is formed on or above the pure silicon layer 130 and located between the pure silicon layer 130 and a CESL material 140′. The CESL material 140′ is formed above the epitaxy layer 160. The CESL material 140′ surrounds an oxide layer material 150′. The CESL material 140′ may be formed from a material including SiO, SiN, SiOC, SiON or SiOCN.

In FIG. 3A, the first dielectric layer material 114A′ and the second dielectric layer material 114B′ and the dummy gate 114C are formed above the active channel sheet 112. The second dielectric layer material 114B′ is formed between the first dielectric layer material 114A′ and the dummy gate 114C. In addition, the first dielectric layer material 114A′ may be formed of a material different from that of the second dielectric layer material 114B′. In an embodiment, the first dielectric layer material 114A′ may be formed from a material including one of SiO, SiN, SiOC, SiON and SiOCN, and the second dielectric layer material 114B′ may be formed from a material including another of SiO, SiN, SiOC, SiON and SiOCN.

As illustrated in FIG. 3B, a patterned hard mask HM is formed over the CESL material 140′, the first dielectric layer material 114A′, the second dielectric layer material 114B′ and the dummy gate 114C, wherein the patterned hard mask HM has at least one opening HMa. The opening HMa exposes the first dielectric layer material 114A′, the second dielectric layer material 114B′ and the dummy gate 114C which define a region of the isolation component.

As illustrated in FIG. 3C, the isolation hole 120a passing through the first dielectric layer material 114A′, the second dielectric layer material 114B′, the dummy gate 114C, a plurality of the active channel sheets 112, a plurality of the SiGe layers 113D and a portion of the substrate 105 is formed, through the opening HMa, by using, for example, etching. In the present embodiment, the entirety of the dummy gate 114C and the entirety of the entirety of the SiGe layers 113D may be removed.

As illustrated in FIG. 3D, the first dielectric layer material 122′, the second dielectric layer material 123′ and the third dielectric layer material 124′ filling the isolation hole 120a and over an upper surface of the structure in FIG. 3C are formed in order by using, for example, deposition. The first dielectric layer material 122′ may be formed of a material including oxide, the second dielectric layer material 123′ may be formed of a material including SiN, and the third dielectric layer material 124′ may be formed of a material including ALD oxide.

As illustrated in FIG. 3E, an oxide layer 10 over the third dielectric layer material 124′ is formed by using, for example, deposition. In an embodiment, the oxide layer 10 may be formed of a material including a plasma enhanced oxide (PEOX), etc. In addition, the oxide layer 10 has a thickness of 150 nm.

As illustrated in FIG. 3F, the oxide layer 10, a portion of the first dielectric layer material 122′, a portion of the second dielectric layer material 123′ and a portion of the third dielectric layer material 124′ in FIG. 3E are removed by using, for example, CMP, etc. After CMP, a planarized surface 100u′ including an upper surface 124u′ of the third dielectric layer material 124′, an upper surface 150u′ of the oxide layer material 150′, an upper surface 114Au′ of the first dielectric layer material 114A′, an upper surface 114Bu′ of the second dielectric layer material 114B′ and an upper surface 114Cu of the dummy gates 114C is formed. Due to the oxide layer 10 in FIG. 3E serving as a sacrificial layer, the upper surface 124u′ has a better flatness, and has no depression recessed with respect to the upper surface 124u′.

As illustrated in FIG. 3G, the dummy gates 114C and the SiGe layers 113D in FIG. 3F are removed by using, for example, etching. After the dummy gates 114C is removed, a plurality of recesses 110al are formed. After the SiGe layers 113D is formed, a plurality of spaces 110a2 is formed. During etching, a portion of the oxide layer material 150′, a portion of the first dielectric layer material 114A′, a portion of the second dielectric layer material 114B′, a portion of the oxide layer material 150′ and a portion of the third dielectric layer material 124′ are removed. After etching, a remaining portion of the third dielectric layer material 124′ forms the third dielectric layer 124, and the third dielectric layer 124 has a recess 124a. In the present embodiment, the recess 124 is formed in the same process of removing the dummy gates 114C and the SiGe layers 113D.

As illustrated in FIG. 3H, a first high-k layer material 111A′ on the recess 110al, the space 110a2 and the recess 124a is formed by using deposition, and then a first metal material 111B′ on the first high-k layer material 111A is formed by using deposition.

Then, a portion of the first metal material 111B′, a portion of the first high-k layer material 111A′, a portion of the CESL material 140′, a portion of the oxide layer material 150′, the first dielectric layer material 114A′ and a portion of the second dielectric layer material 114B′ are removed, by using CMP, to form the semiconductor device 100 as illustrated in FIG. 1. After CMP, a remaining portion of the first metal material 111B′, a remaining portion of the first metal material 111B′, a remaining portion of CESL material 140′, a remaining portion of the oxide layer material 150′, a remaining portion of the first dielectric layer material 114A′ and a remaining portion of the second dielectric layer material 114B′ form the first metal 111B, the first high-k layer 111A, the CESL 140, the oxide layer 150, the first gate spacer 114A and the second gate spacer 114B as illustrated in FIG. 1 respectively.

The manufacturing method of the semiconductor device 200 in FIG. 2 includes the processes the same as or similar to those of the semiconductor device 100, and it will be not repeated here.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a plurality of active components and an isolation component. Each active component includes a plurality of active channel sheets vertically stacked and a metal gate. The isolation component isolates the adjacent two of the active components and includes a plug structure. The plug structure is formed of a material the same as that of the metal gate. Accordingly, a planarized surface of the semiconductor device formed in CMP process may have better flatness.

Example embodiment 1: a semiconductor device includes a plurality of active components and an isolation component. Each active component includes a plurality of active channel sheets vertically stacked and a metal gate. The isolation component isolates the adjacent two of the active components, and includes a plug structure. The plug structure is formed of a material the same as that of the metal gate.

Example embodiment 2 based on Example embodiment 1: the plug structure is a high-k layer.

Example embodiment 3 based on Example embodiment 1: the metal gate includes a first high-k layer and a first metal, the plug structure includes a second high-k layer and a second metal, the first high-k layer is formed of a material the same as that of the second high-k layer, and the first metal is formed of a material the same as that of the second metal.

Example embodiment 4 based on Example embodiment 1: the isolation component includes a dielectric layer, and the plug structure is formed above the dielectric layer.

Example embodiment 5 based on Example embodiment 1: the isolation component includes a first dielectric layer, a second dielectric layer and a third dielectric layer, the second dielectric layer is formed between the first dielectric layer and the third dielectric layer, the second dielectric layer covers a lateral surface of the plug structure, and the third dielectric layer covers a bottom of the plug structure.

Example embodiment 6 based on Example embodiment 1: the metal gate has a first upper surface, the plug structure has a second upper surface, and the first upper surface and the second upper surface are substantially flush with each other.

Example embodiment 7 based on Example embodiment 1: the plug structure is a top portion of the isolation component.

Example embodiment 8 based on Example embodiment 1: the semiconductor device further includes an isolation hole isolating the adjacent two of the active components. The isolation component fills the entirety of the isolation hole.

Example embodiment 9 based on Example embodiment 1: the plug structure has a height ranging between 3 nanometers to 5 nanometers.

Example embodiment 10: the semiconductor device includes a plurality of active components, an isolation hole and an isolation component. Each active component includes a plurality of active channel sheets vertically stacked and a metal gate. The isolation component includes a dielectric structure and a plug structure. The dielectric structure is formed on a sidewall of the isolation hole. The plug structure is formed on the dielectric structure. The plug structure is formed of a material different from that of the dielectric structure.

Example embodiment 11 based on Example embodiment 10: the metal gate includes a first high-k layer and a first metal, the plug structure includes a second high-k layer and a second metal, the first high-k layer is formed of a material the same as that of the second high-k layer, and the first metal is formed of a material the same as that of the second metal.

Example embodiment 12 based on Example embodiment 10: the plug structure is formed above the insulation layer.

Example embodiment 13 based on Example embodiment 10: the dielectric structure includes a first dielectric layer, a second dielectric layer and a third dielectric layer, the second dielectric layer is formed between the first dielectric layer and the third dielectric layer, the second dielectric layer covers a lateral surface of the plug structure, and the third dielectric layer covers a bottom of the plug structure.

Example embodiment 14 based on Example embodiment 10: the metal gate has a first upper surface, the plug structure has a second upper surface, and the first upper surface and the second upper surface are substantially flush with each other.

Example embodiment 15 based on Example embodiment 10: the plug structure is a top portion of the isolation component.

Example embodiment 16 based on Example embodiment 10: the isolation component fills the entirety of the isolation hole.

Example embodiment 17 based on Example embodiment 10: the plug structure has a height ranging between 3 nanometers to 5 nanometers.

Example embodiment 18: a manufacturing method for a semiconductor device includes the following steps: forming a plurality of active components on a substrate, wherein each active component includes a plurality of active channel sheets vertically stacked; forming an isolation hole to isolate the adjacent two of the active components; forming a dielectric structure of an isolation component within the isolation hole; forming a plug structure of the isolation component within the isolation hole; and forming a metal gate on the corresponding active component, wherein the plug structure is formed of a material the same as that of the metal gate.

Example embodiment 19 based on Example embodiment 18: the plug structure is a high-k layer.

Example embodiment 20 based on Example embodiment 18 in forming the metal gate on the corresponding active component, the metal gate includes a first high-k layer and a first metal; in forming the plug structure of the isolation component within the isolation hole, the plug structure includes a second high-k layer and a second metal; wherein the first high-k layer is formed of a material the same as that of the second high-k layer, and the first metal is formed of a material the same as that of the second metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of active components, wherein each active component comprises a plurality of active channel sheets vertically stacked and a metal gate; and
an isolation component isolating the adjacent two of the active components, and comprising a plug structure;
wherein the plug structure is formed of a material the same as that of the metal gate.

2. The semiconductor device as claimed in claim 1, wherein the plug structure is a high-k layer.

3. The semiconductor device as claimed in claim 1, wherein the metal gate comprises a first high-k layer and a first metal, the plug structure comprises a second high-k layer and a second metal, the first high-k layer is formed of a material the same as that of the second high-k layer, and the first metal is formed of a material the same as that of the second metal.

4. The semiconductor device as claimed in claim 1, wherein the isolation component comprises a dielectric layer, and the plug structure is formed above the dielectric layer.

5. The semiconductor device as claimed in claim 1, wherein the isolation component comprises a first dielectric layer, a second dielectric layer and a third dielectric layer, the second dielectric layer is formed between the first dielectric layer and the third dielectric layer, the second dielectric layer covers a lateral surface of the plug structure, and the third dielectric layer covers a bottom of the plug structure.

6. The semiconductor device as claimed in claim 1, wherein the metal gate has a first upper surface, the plug structure has a second upper surface, and the first upper surface and the second upper surface are substantially flush with each other.

7. The semiconductor device as claimed in claim 1, wherein the plug structure is a top portion of the isolation component.

8. The semiconductor device as claimed in claim 1 further comprising:
an isolation hole isolating the adjacent two of the active components;
wherein the isolation component fills the entirety of the isolation hole.

9. The semiconductor device as claimed in claim 1, wherein the plug structure has a height ranging between 3 nanometers to 5 nanometers.

10. A semiconductor device, comprising:
a plurality of active components, wherein each active component comprises a plurality of active channel sheets vertically stacked and a metal gate;
an isolation hole isolating the adjacent two of the active components; and
an isolation component formed within the isolation hole and comprising:
a dielectric structure formed on a sidewall of the isolation hole; and
a plug structure formed on the dielectric structure;
wherein the plug structure is formed of a material different from that of the dielectric structure.

11. The semiconductor device as claimed in claim 10, wherein the metal gate comprises a first high-k layer and a first metal, the plug structure comprises a second high-k layer and a second metal, the first high-k layer is formed of a material the same as that of the second high-k layer, and the first metal is formed of a material the same as that of the second metal.

12. The semiconductor device as claimed in claim 10, wherein the plug structure is formed above the insulation layer.

13. The semiconductor device as claimed in claim 10, wherein the dielectric structure comprises a first dielectric layer, a second dielectric layer and a third dielectric layer, the second dielectric layer is formed between the first dielectric layer and the third dielectric layer, the second dielectric layer covers a lateral surface of the plug structure, and the third dielectric layer covers a bottom of the plug structure.

14. The semiconductor device as claimed in claim 10, wherein the metal gate has a first upper surface, the plug structure has a second upper surface, and the first upper surface and the second upper surface are substantially flush with each other.

15. The semiconductor device as claimed in claim 10, wherein the plug structure is a top portion of the isolation component.

16. The semiconductor device as claimed in claim 10, wherein the isolation component fills the entirety of the isolation hole.

17. The semiconductor device as claimed in claim 10, wherein the plug structure has a height ranging between 3 nanometers to 5 nanometers.

18. A manufacturing method for a semiconductor device, comprising:
forming a plurality of active components on a substrate, wherein each active component comprises a plurality of active channel sheets vertically stacked;
forming an isolation hole to isolate the adjacent two of the active components;
forming a dielectric structure of an isolation component within the isolation hole;
forming a plug structure of the isolation component within the isolation hole; and
forming a metal gate on the corresponding active component;
wherein the plug structure is formed of a material the same as that of the metal gate.

19. The manufacturing method as claimed in claim 18, wherein in forming the plug structure of the isolation component within the isolation hole, the plug structure is a high-k layer.

20. The manufacturing method as claimed in claim 18, wherein in forming the metal gate on the corresponding active component, the metal gate comprises a first high-k layer and a first metal; in forming the plug structure of the isolation component within the isolation hole, the plug structure comprises a second high-k layer and a second metal;
wherein the first high-k layer is formed of a material the same as that of the second high-k layer, and the first metal is formed of a material the same as that of the second metal.
